(19) United States
(12) Patent Application Publication
(10) Pub. No.: US 2023/0342185 A1
(43) Pub. Date: Oct. 26, 2023

(54) Boolean Network Improvement

(71) Applicant: RapidSilicon US, Inc, Los Gatos, CA (US)

(72) Inventor: Thierry Besson, Antibes (FR)

(21) Appl. No.: 18/152,753

(22) Filed: Jan. 10, 2023

Related U.S. Application Data
(60) Provisional application No. 63/426,615, filed on Nov. 18, 2022.
(60) Provisional application No. 63/332,818, filed on Apr. 20, 2022.

(51) Int. Cl. G06F 9/46

(52) U.S. Cl. CPC G06F 9/466

(57) ABSTRACT

Technology is described for improvement of a Boolean Network. The method can include applying a plurality of transformation scripts to a Boolean Network to form a plurality of levels of a transformation tree with nodes representing transformation metrics for the transformation scripts applied to the Boolean Network. The nodes in individual levels of the transformation tree can be prioritized based in part on a cost function that uses the transformation metrics to identify an improved node as compared to less improved nodes in each of the plurality of levels of the transformation tree. Another operation may be identifying a transformation script using improved nodes of the transformation tree.

### PRIORITY DATA

This application claims the benefit of U.S. Provisional Application No. 63/426,615, filed Nov. 18, 2022, and U.S. Provisional Application No. 63/332,818, filed Apr. 20, 2022, both of which are incorporated herein by reference.

### BACKGROUND

The primary logic elements forming Field Programmable Gate Arrays (FPGAs) are Look-Up Tables (LUTs). LUTs are capable of implementing generic Boolean logic functions. Specific circuits are also added to provide additional performance such as DSP (digital signal processing) or memory blocks. A traditional FPGA Electronic Design Automation (EDA) design flow addresses logic synthesis and physical implementation. In this process, the general logic of a user circuit is manipulated and tailored to the proposed FPGA target by logic synthesis and consists of logic optimization and technology mapping.

Logic optimization is technology independent and aims at reducing the complexity of an abstract logic circuit by minimizing target objectives such as the size of the logic network, its depth or its netlist count. Then, technology mapping maps the logic circuit to the generic logic primitives available in the target FPGA, i.e., the LUTs. Logic manipulation essentially consists of manipulating the logic network using a sequence of individual and simple transformations, called a recipe. To achieve an optimal design, a logic synthesis engineer would have to use a very unique recipe per design, which can be generally unpractical to create for each logic network design. Instead, logic synthesis engineers provide standard recipes that provide good trade-offs across many designs.

Over the past few decades, Field-Programmable Gate Arrays (FPGAs) have established themselves as a dominant player in the digital design landscape thanks to a flexibility and cost-effectiveness not achievable by semi-custom circuits. However, this comes at a performance, power consumption, and area utilization trade-off, and this drives the desire for highly efficient FPGA design implementations that are minimized as much as possible. In particular, logic synthesis which aims at translating Register Transfer Level (RTL) design description into gate-level implementations is an important step that impacts the performance of the resulting logic circuit. This is even more true in the context of Field Programmable Gate Arrays (FPGAs), where optimizing the gate-level implementation of a design has a strong impact on both the area (in terms of LUT resource utilization) and performance (in terms of maximum frequency) of the design.

Logic synthesis may broadly be divided into two steps: technology independent optimization, which optimizes the logic of a design, and technology dependent optimization, which maps that logic onto a library of primitives while optimizing the mapping for some cost function. Technology independent optimization typically consists of transforming the RTL into a homogeneous Directed Acyclic Graph (DAG) and manipulating this graph towards a given optimal target using a sequence of transformations. The set of transformations is usually called a recipe and achieving optimality would use a unique recipe per logic design. Recipes in commercial tools are tailored by experienced engineers to achieve good trade-offs across many designs.

### BRIEF DESCRIPTION OF THE DRAWINGS

FIG. 1 is a block diagram illustrating an example graph of optimization explorations.

FIG. 2 is an example chart of pseudocode for optimizing a mapped network.

FIG. 3 is an example chart of pseudocode for exploring a step and removing less desirable transformation netlists.

FIG. 4 is flowchart illustrating an example of a method for improvement of a Boolean Network.

FIG. 5a is a block diagram illustrating an example of a prior approach to optimization.

FIG. 5b is a block diagram illustrating an example of optimization using the design explorer.

FIG. 6 is a block diagram illustrating an example of applying two optimizations using two threads in parallel.

FIG. 7 is a block diagram illustrating an example of a tree structure formed while working to identify better optimizations at each level of the tree.

FIG. 8 is a block diagram illustrating an exploration tree for identifying a better optimization path.

FIG. 9 is a block diagram that provides an example illustration of a computing device that can be employed in the present technology.

### DETAILED DESCRIPTION

Reference will now be made to the examples illustrated in the drawings, and specific language will be used herein to describe the same. It will nevertheless be understood that no limitation of the scope of the technology is thereby intended. Alterations and further modifications of the features illustrated herein, and additional applications of the examples as illustrated herein, which would occur to one skilled in the relevant art and having possession of this disclosure, are to be considered within the scope of the description.

Look-up Table (LUT) synthesis is an important step in any FPGA-based design flow because this operation significantly impacts the quality of results (QoR) of the final design solution, both in term of resource utilization and/or performance. In fact, QoR is one of the important goals in any design flow because of the ongoing work to get smaller, faster and lower power designs. This technology provides a design explorer (DE), which may be used with a logic synthesizer with verification (e.g., “ABC”) to form a combined tool or system to explore multiple optimization options and identify better optimization paths for optimization script application. The design explorer may be used with any logic synthesizer, as desired.

The present technology may use artificial intelligence and parallel exploration of dynamically built synthesis scripts. Parallel exploration may be performed by using some intelligent design techniques (dynamic and AI-based) in order to have a design space efficiently explored or covered to find a good LUT mapping solution. This approach can help to significantly improve QoR both in terms of LUT utilization and logic level reduction. For example, the design explorer (e.g., exploration engine) may be able to get around 12% LUT utilization reduction versus previously existing commercial tools.

The nature of the problem is that no single recipe exists to optimize many types of FPGA logic designs or similar designs. In the present technology, heuristics and tool intelligence can be put in place to adjust recipes applied to each design. The design explorer (e.g., “ABC-DE”) or exploration engine can build on-the-fly synthesis recipes using artificial intelligence and parallel exploration techniques. The design explorer can be integrated into known logic synthesizers, (e.g., such as “ABC” or “LSOracle”) to perform the actual optimization of the logic design. Targeting primarily LUT optimizations, the design explorer or exploration engine may apply a breadth-first exploration to navigate in a complex optimization space. When integrated with a logic synthesis engine (e.g., such as ABC or LSOracle), the design explorer (i.e., exploration engine) can significantly improve QoR both in terms of LUT utilization and logic level reduction.

Autonomous Design Decision in EDA (Electronic Design Automation) Decision intelligence can be used to guide EDA decisions and boost design closure for both ASICs and FPGAs. Most previously existing design intelligence can be grouped into two main categories:
1. Performing parameter tuning in the EDA tool, e.g., adjusting heuristic parameters, deciding on-the-go to perform additional processing, etc.
2. Exploring the sequence of operations, in this case synthesis transformations, using an iterative process.

In this second category, one previously existing system used a fully autonomous framework that artificially produces design-specific synthesis flows without human guidance and baseline flows, using Convolutional Neural Network (CNN). To limit the overhead and black box operations from neural network technologies, a domain specific multi-armed bandit algorithm was proposed to explore logic manipulation space. A few of the limitations in this approach were: an explicit enumeration of transformations, a stiff constant number of transformations was used, and a lack of sharing of similar transformations between sequences. In the present technology, these limitations are avoided by considering any length of transformation sequences. Transformations go on as long as improvement goes on. Common sub-sequences can also be shared which leads to an exploration tree representation model and different levels of optimization strengths for a given transformation, which are useful especially if the exploration gets stuck in a local minimum.

### Design Explorer

The design explorer can be an intelligent exploration engine capable of integrating with traditional logic synthesis commands (e.g., ABC or LSOracle) to address both Boolean Network optimizations and K-LUT mapping, and capable of acting as an automated recipe creator as opposed to having a synthesis expert created recipes. The design explorer can also operate as a wrapper to the logic synthesizer and does not require intervention into the underlying synthesis engine which may be used with minimal modifications.

It can be useful to know how logic synthesis and LUT-based technology mapping have been generally addressed in practice in the past. Generally, a design engineer would try to develop one or more scripts made of low granularity synthesis commands to provide to the logic synthesis tool in order to get a good optimization for a given design. One issue with this approach is that there may be different “best” scripts for different designs. It may happen that one specific synthesis command works well for a specific design and not for another kind of design. Therefore, logic synthesis tool users generally try to find a good trade-off script such that, on average, this script will behave correctly on any type of design. The problems with this approach may be:
it is time consuming for any user of a synthesis engine to find the “best” script for a design,
the synthesis user may not use the correct commands or may miss some commands that can work well in some specific configurations or logic structures,
the “best” so-called synthesis script is an average script, e.g., it may return some good solutions on average but may be still far from a “best” solution for a given design,
a synthesis engine expert user can be biased and use a sub-set of commands because of some well-established past experience and this may result in blind spots.

For all these reasons, the present technology defines processes and systems that may build up an effective script automatically on the fly by doing synthesis command explorations without any assumptions. The automatically generated script may be design sensitive, which means the finals script can be different from one design to another, and the process can be driven by the cost function to be optimized.

### Defining the Basic Transformations

An L6-transformation may be any transformation that takes as input a LUT6 mapped network and returns a new LUT6 mapped network. One of the most important parameters is the definition of the L6-transformations themselves. In the example of using ABC, the transformations can correspond to the most used ABC optimizations and mapping commands from ABC9 and ABC, such as: &if, &lf, &dch, &satlut, &mfs, &shrink, &synch2, mfs2, . . . , etc., with associated parameters and parameter values. The sequence on how to call these commands, which associated parameter(s) to use, or which values to set, are obviously important in providing improved quality of results (QoR) from the design explorer investigation. The role of the exploration is to find the most improved sequence with desirable parameters and the value settings. While a LUT6 is discussed here, a LUT of any size may be used (e.g., LUT 8, K-LUT, etc.)

### Exploration of Synthesis Solutions: Basic Complexity Analysis

Let n be the number of L6-transformations. If n L6-transformations are applied on a given LUT6 mapped network then n new LUT6 mapped networks are generated. If the same transformations are re-applied on the n previous LUT6 mapped networks, then n² new LUT6 mapped networks can be generated. After applying p successive L6-transformations then n^{p} LUT6 mapped networks are produced. The total number of created networks T(p,n), after p successive L6-transformations with n L6-transformations at each step, is:

$$T ( p , n ) = {\sum }_{i = 1}^{p} {n}^{i}$$

This means that at each step i we sum up the number of new networks at that step. We can consider the very first network as another visited network so we can start the index i at value 0 corresponding to the known formula for n≠1:

$$T ( p , n ) = {\sum }_{i = 1}^{p} {n}^{i} = \frac{( {n}^{p + 1} - 1 )}{n - 1}$$

At each step i, the number of transformations is not a constant n but a number >1 related to that step i which would be s(i) for i=1, . . . , p. Therefore, more generally the total number of visited networks would be:

T(p,s(1), . . . s(p))=Σᵢ₋₁^{p}n^{s(i)}

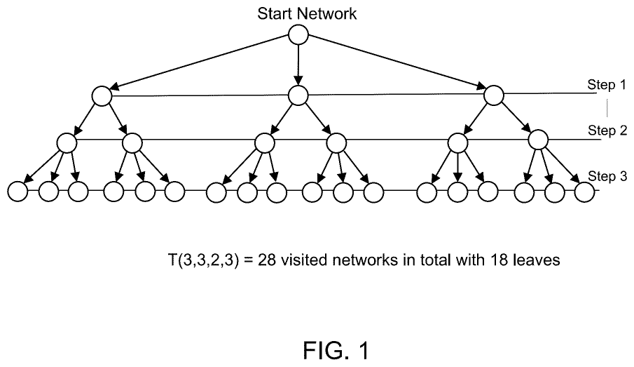

An example of a graph representing such an exploration can be illustrated in FIG. 1 and the graph is basically a tree.

In this example of FIG. 1, we consider three transformations applied on the starting network at step 1. On the three created networks, two transformations are applied on each of the networks at step 2, so six networks are created at end of step 2. On these six networks three transformations are applied at step 3, so that finally 18 leaf networks exist at end of step 3. In total, 28 networks may be created corresponding to T (3,3,2,3).

Further, the exploration strategy may be based on this step by step approach and a breadth-first exploration strategy. Each step may have different number of L6-transformations in the general case.

### Breadth-First Exploration

As mentioned above, the design exploration can be implemented through a breadth-first strategy by creating, layer by layer, new networks at step i resulting in L6-transformations from networks at step i−1. This strategy may have several benefits:
All L6-transformations involved at step i can be run concurrently. It is helpful, but not absolutely required, for the n such L6-transformations take about the same amount of execution-time in order to better leverage parallelism.
Once the L6-transformations at step i are done, it is straight forward to evaluate the target cost function on the newly created networks (a subset of all the networks) and sort them according to this cost function from “best” to “worst”. Having the global view of this subset of networks versus the previously visited networks, enables applying pruning techniques on this new subset to control the tree explosion.
   Design Explorer with a Logic Synthesizer

The breadth-first process of the design explorer when used with a logic synthesizer (e.g., ABC-DE) may have to deal with two issues: 1) The process may have to deal with an exploration space explosion to control and may have to work to avoid run time blowup. 2) The process may have to deal with local minimum cases in order to improve QoR.

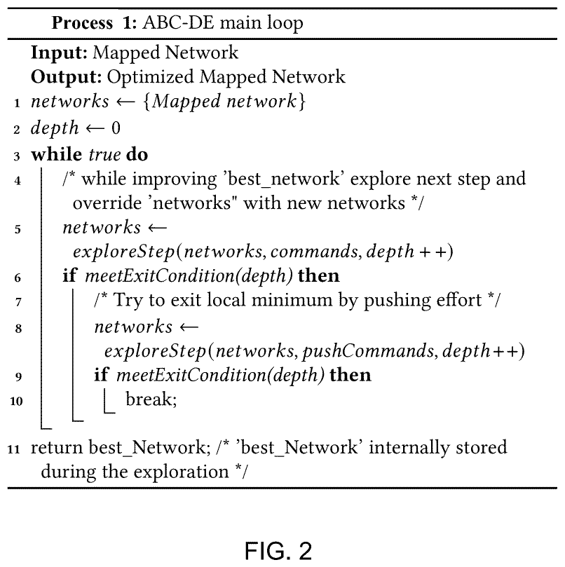

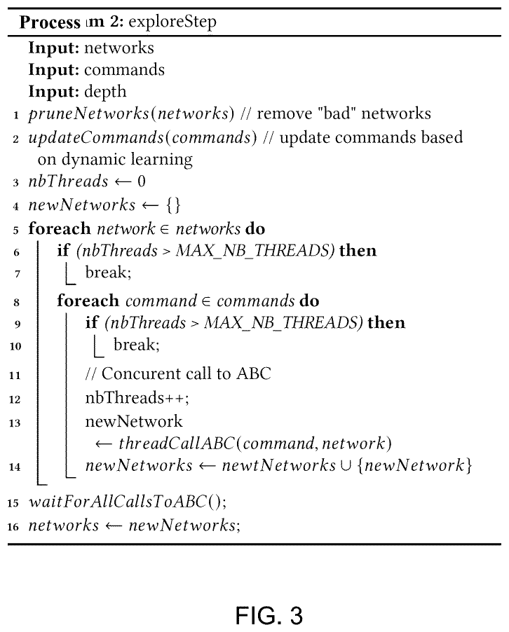

Process 1 in FIG. 2 illustrates example top level operations for the design explorer in pseudocode form. Process 2 in FIG. 3 illustrates an example of pseudocode for the underlying procedure “exploreStep” that may launch the threads corresponding to an exploration of a pair {ABCcommand, Network} at a given step. This procedure may first call “pruneNetworks” to remove “bad” network candidates. “Smart pruning” and “slotting” can be performed as explained later.

In FIG. 3, “updateCommands” can then be called to tune/remove/create logic synthesizer (e.g., ABC) optimization commands based on the learning process during exploration. Each command may have a weight and each weight may be updated according to the previous success or failure of the optimization command applied on the networks. Weight for each command can be increased upon success and decreased upon failure. When a command falls below a weight threshold, a command can be removed because of a low return of investment.

During hill climbing, optimization command options can be “pushed” in the sense that the optimization command may be invoked in a stronger optimization mode. The optimization commands tuning process can evolve dynamically along the exploration and can be different from one design to another. The “meetExitCondition” can simply compare the step number at which the “Best network” has been found and the current step number. After a maximum (e.g., Max) given number of steps where the improved network or “best network” has been found (typically 5 steps), this procedure can return true and inform that the exploration can exit because the improved network or “best network” could not be improved after the maximum steps. This corresponds to a local minimum situation. In that case, a specific exploration with specific extended configuration or “pushed” optimization commands can be called that will try to exit from the current local minimum. This is the hill-climbing phase. If the “meetExitCondition” is still true, e.g. we did not improve the current improved network or “best network” and it is not possible to exit from the local minimum, then we break the main loop, exit and return the final improved network or “best network” for application to the design.

Dealing with Exploration Space Explosion

As previously discussed, the exploration space in terms of number of visited solutions has a lower bound in the order of O (mp+1) where m would be the minimum number of L6-transformations applied on a network at a given step and p the total number of steps. Because of the intrinsic explosive nature of the proposed process, pruning strategies may be helpful.

### Smart Pruning

In one configuration, smart pruning may be used. Consider a set of mapped networks at step i on which a set of L6-transformations may be applied, exploring the best potential pair candidates {mapped network, L6-transformation} and rejecting the potential “bad” ones may be called “smart pruning”. In order to estimate the potential good pair candidates {mapped network, L6-transformation} to explore, two parameters may be considered: the mapped network characteristics and the L6-transformation. Regarding the mapped network, a natural pruning heuristic can reject the ones that are relatively distant from the current best mapped network. This relative distance can be given by the cost function desired to be minimized, like LUT6 count for Area, LUT6 lvl count (+LUT count as tie breaker) for a delay minimization, WNS (worst negative slack) and TNS (total negative slack) with real STA (Static Timing Analysis), etc. Other mapped networks characteristics can be considered as tie breakers if many networks have the same cost, like max depth, average depth, and max fanout. As an example, if the current best mapped network has 1000 LUT6, and two mapped networks are being considered for exploration with 1003 LUTs and 1090 LUTs, then the system will visit the first one in priority since its relative distance to the best network is only 3 LUT6s (and the network with 1090 might be pruned). This can be considered a best distance type of pruning.

Regarding the L6-transformations analysis, AI techniques can be used which have a better chance to give an improved QoR return. These AI techniques may be based on some dynamic that has been selected for the next exploration iteration, and upon success the technique's success rate will be increased. On the other hand, the technique's success rate or weighting may be decreased in case of failure. When the success rate goes below a given threshold then the L6-transformation is considered as inefficient and is removed from the L6-transformations set. The L6-transformation success rate may be different from one design to another as this reflects the fact that in general, some transformations work well for some specific designs and not for other type of designs. This means the exploration is adaptive to the input design and can learn on the fly (or at run-time) which L6-transformations to focus on as the process progresses.

### Slotting

Once smart pruning has been considered at step i, plenty of pairs {mapped network, L6-transformation} may still be explored at step i+1. Since CPU resource limitations can be considered, the parallel exploration can start at step i+1, and an extra pruning procedure can be used that may be called “slotting”. In this slotting procedure, a subset of prioritized pairs (e.g., good pairs) may be accepted in order to not exceed a given number of threads. For example, if after the smart pruning there are 300 prioritized pairs and we cannot exceed 200 threads, there will still be 100 prioritized pairs to remove so that only 200 pairs can be explored. In order to do so, various strategies may be used. The first one is to sort the 300 pairs according to a cost function and launch an exploration thread for the first 200 pairs. Another strategy can be to launch even less than 200 threads (slot size reduction) in case the exploration is in a phase where it goes smoothly and significantly improves the current best mapped network. It may not be necessary to run too many threads when the exploration is performing well and is in a phase where improvements are significant. On the other hand, it can make sense to increase the number of threads and reach the limit of executable threads for CPU resources when the network becomes harder to improve. To summarize, a constant slot size strategy or a dynamic slot strategy may be used so that pairs {mapped network, L6-transformation} can go through the next exploration step. A slot strategy can be used that provides the same QoR (Quality of Results) but with less CPU (central processing unit) resource utilization.

Dealing with Local Minimum

The exploration engine may rely on an incremental process for improving a current improved solution or best solution. Along this process, it may happen that the current improved solution cannot be improved at some point and that the process may get stuck in a local minimum. There are at least two methods to minimize local minimum situations that can impact the QoR (quality of results). A first method of avoiding local minimums is by avoiding them as much as possible by carefully characterizing the type of L6 transformations so that certain types of transformations are used at a specific stage of the exploration. A second method of avoiding local minimums is by finding efficient and smart techniques to exit from local minimums, and such a method may be called a “hill-climbing” technique.

In one example, L6-transformations can be used to reduce local minimum situations. A local minimum situation is where the exploration process is unable to improve the current improved solution and eventually starts to provide worse solutions. Exiting from this situation may be called “hill-climbing” and it can be a difficult problem. To avoid these kinds of situations (or at least to minimize them), defining strong optimizations or transformations with high effort values at the beginning may create more local minima and at a faster pace. This behavior can look like “simulated-annealing” behavior where it is important at the beginning to not use intensive/high effort optimization procedures with high effort parameters. Indeed, if intensive effort optimizations are started right away, there is a good chance of getting stuck very quickly in a local minimum. Therefore, the sequence of the set of transformations can be organized such that the first sets of optimizations may use light/medium-weight optimizations and the later sets of optimizations may apply stronger optimizations when local minima are encountered. The difference as compared to “simulated-annealing” though is that “simulated-annealing” is a continuous process of using stronger and stronger effort optimizations based on a temperature factor continuously cooling down. In the present case, a sequence of light-to-medium weight effort optimizations are applied followed by strong ones only when facing a local minimum. This means that after resolving a “hill-climbing” situation, the exploration procedure can get back to a normal usage of low/medium effort L6-transformations until facing a new local minimum situation. Some example pseudocode for the process can be shown in FIG. 2.

Some hill climbing strategies will now be provided. In order to exit from a local minimum, two processes can be described. In a first process, new L6-transformations can be used that were not used in the low-medium effort phase when facing a local minimum. Since it is difficult to exit from local minimums with the current L6-transformations that are being applied, it can useful to apply new ones when facing the local minimum. In a second process, the engine can continue to use the low-medium effort L6-transformations already used up to that point in the exploration but with more-intensive optimization options or configuration setting. For these two kinds of approaches, specific types of L6-transformations can be used.

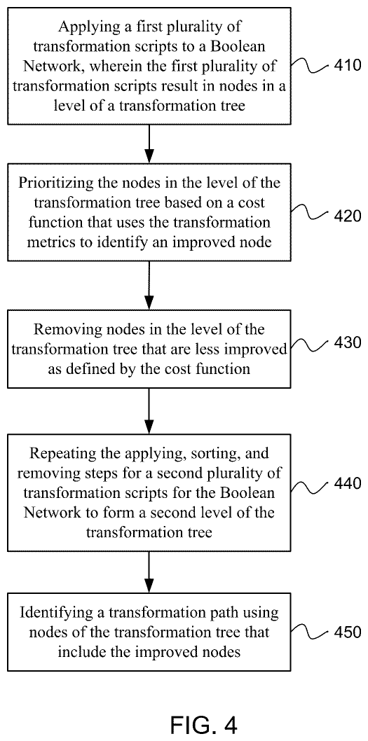

FIG. 4 illustrates an example flow chart illustrating a method for improvement of a Boolean Network. The method may include applying a first plurality of transformation scripts or optimization operations to a Boolean Network, as in block 410. The first plurality of transformation scripts may result in transformation metrics that are represented as nodes in a level of a transformation tree. The plurality of transformation scripts may be the application of the at least two transformation or optimization to a netlist at each level of the transformation tree.

The nodes in the level of the transformation tree may be prioritized based in part on a cost function that uses the transformation metrics to identify an improved node as compared to other less improved nodes, as in block 420. For example, prioritization may occur by selecting the improved node that minimizes the cost function (e.g., the smallest number of LUTs, delay minimization, power minimization, etc.). The improved node can be placed in a preferred or desired transformation path or transformation script. More than one cost function may be used for prioritization depending on the application.

Nodes in the level of the transformation tree that are less improved as defined by the cost function and/or as compared to the improved nodes can be pruned or removed from consideration for further transformations or optimizations, as in block 430. The applying, sorting, and removing steps can be repeated for a second plurality of transformation scripts for the Boolean Network to form a second level of the transformation tree, as in block 440. For example, a plurality of fine grained transformations can be applied to the Boolean Network to create a first set of nodes in the transformation tree. Then a plurality of coarse grained transformations (e.g., stronger transformations or optimizations) can be applied to the Boolean Network to create a second set of nodes in the transformation tree that descend from the first set of nodes created by the plurality of fine grained transformations. The fine grained transformations and/or coarse grained transformations may be repeated until a defined number of iterations is reached or until improvements in the transformation metrics stop occurring. The improvement transformations or modifications may be applied incrementally and the first plurality of transformation scripts may have smaller improvement transformations than the second plurality of transformation scripts. In one example configuration, fine grained transformations are applied for the first plurality of transformation scripts, and the fine grained transformations provide a smallest available unit of logic reduction.

Examples of fine grained transformations may be one command optimizations, such as: dch, simi2, if, etc., which can be applied to the Boolean Network or netlist. These single command optimizations may be combined together into several small passes. Two or three fine grained optimizations can be applied at one level (opt 1, opt 2, opt 3). More specifically, fine grained transformations may be the most basic transformation or the smallest optimization that may be performed.

A more complex or compound optimization can be considered a coarse grained optimization. Coarse grained optimizations can be stronger or more complex optimizations. In addition, a coarser optimization may be the combination of the more complex commands for optimizations (opt 1-opt 2-opt 3) but then the optimizations may be applied to quickly and the transformations may get stuck in a local minimum.

For example, the command “if” may be used to transform the logic into optimized LUTs. This command may have some options. These options can also be applied to offer a larger scope of optimizations. There is just one command but using options several commands with several strengths can be created. A reduced strength version of the command may stop as soon as there are 6 conflicts. A more coarse grained version may have the conflicts increased to 8 or 10 and then more exploration or optimization can occur in that pass. In a more specific example, the fine grained optimization may be “if” with the default value of 6 conflicts. Furthermore, a version can be created which is stronger and much more time consuming with many more options that are requested.

To maintain the transformations in the design explorer, the design environment may provide a container where a designer can place and store the transformations. The user or design can then add the transformation to the container and the transformation may be applied to the digital network. Accordingly, the user may define the optimization, and when the optimization is used, the system can determine whether the optimization improves the digital network or Boolean Network.

When optimizations are being applied, if only area based transformations are used, then this may not provide good delay solutions and vice-versa. In the set of transformations, it is useful to provide some delay centric and some area centric optimization. The design explorer can vary their application and ultimately a better outcome may be provided than by hand crafting an optimization script. The design explorer can figure out a route or which series of optimization to apply at each level of the tree. The designer does not know the optimization route that has been taken until the exploration has taken place.

The transformation scripts can use an individual process to execute each transformation script, which may allow some transformations to execute in parallel. The transformation scripts for the Boolean Network can be executed using multi-threading with an upper bound value or threshold value for a number of individual processes to be used per level of the transformation tree. The number of individual processes may be based on a desired amount of computing capability to be consumed or a computing capability constraint.

A transformation path can be identified using nodes of the transformation tree that include the improved nodes, as in block 450. This may include recording a transformation path for the transformation tree with the improved nodes and/or a reduced logic solution for the Boolean Network. More specifically, a transformation path (e.g., a final transformation script) can be identified through nodes of the transformation tree that have a desirable cost as defined by the cost function and/or have a reduced logic solution compared to other paths in the transformation tree. The transformation path (e.g., a transformation script) may include optimizations from one node in each level of the transformation tree. In addition, the transformation script that is identified or created can have a depth-wise path through the transformation tree using an improved node (e.g., a best node) in each level of the transformation tree. An optimization goal of the transformation path may be at least one of: a reduced chip wafer area, a reduced delay, a power minimization or an improved combination of reduced chip wafer area, reduced delay and power minimization.

As described earlier, the exploration can be a breadth first search that is applied to the logic design or the LUTs. N small transformations can be applied in parallel which may result in N different logic designs. When all the transformations are complete, the logic designs can be analyzed and the designs that are not cost effective or do not optimize the cost function can be removed or pruned. While the tree can become large, the tree can be pruned based in part on cost functions. This enables a convergence on a valuable optimization script that is a good fit and meets the cost function for each design pass or output of a logic design. This technology can provide a good fit or sometimes a best fit for optimizing a varied number of LUT designs. The optimizations may optimize the area, delay or power. Sometimes the best area optimization might be through the logic optimization because when you flatten the logic this may result in a reduced area solution. The design explorer may find this type of unexpected optimization.

As discussed earlier, the statistics for successfully applied transformation scripts may also be tracked. For example, statistics for transformation scripts which are selected as improved nodes can be tracked over time to determine which transformation scripts to include in transformation paths. Similarly, tracking statistics for transformation scripts which are seldom selected can be tracked to determine which transformation scripts to discard due to lack of use or lack of improved output. This may enable a synthesis and optimization suite or synthesis tool to build a library of useful transformation scripts. The system may store the transformation scripts in a transformation script library for nodes with a selection rate and use above a selection threshold.

The designs being created may be written in register transfer level (RTL) design format (e.g., Verilog or VHSIC Hardware Description Language (VHDL)). The language may be converted into a physical design that is desired to be efficient and as small as possible (e.g., the die size or area). In addition, there is a desire for a fast clock frequency, reducing the depth of the logic, and optimized power use. The desire for optimization can be attained by 1) minimizing area; 2) minimizing clock frequencies (tick); and 3) minimizing power consumption.

As explained, in the past, an expert would write the sequence of optimizations in a script. The script would be in fixed form. The script would focus on minimizing area, delay (clock frequency), and/or power consumption. Since the scripts were written and researched over time using many designs to provide the scripts, the scripts were static and hard-coded. In contrast, the present technology can dynamically find a greatly improved script or better script (e.g., the best script) for optimizing the LUT design by exploration. The design explorer may explore small transformations and combine the transformations in many permutations. For example, the optimization may improve the area and clock frequency. The system can check the design to see if the optimized design is better or not, and then the process works to find the most improved path (e.g., the best path).

In the past, when designers would apply a static script to synthesized LUT design, sometimes the result of the script may have provided a good improvement and other times not much improvement at all. Static scripts may improve some designs better than others. Thus, designers generally tried to find static scripts that worked well for families of designs, where some scripts work better for one type of design and other scripts work better for other types of designs. In contrast, the present technology provides dynamic scripts that provide a good trade off solution for all types of designs. The dynamic script can adapt to the type of design using exploration. This results in better QoR from the dynamically created scripts. Some designs could be six times smaller using this dynamic adaptation of script optimization application.

To reiterate and summarize to some extent, when the design explorer creates the exploration tree, an improved solution or even a best solution can be found by minimizing a cost function. The desired optimizations may be found through the breadth first search. In each level, the leaves are compared to the current solution. Then the leaves that are not good solutions are pruned. When you identify a good route for a design that route can be re-played in the future, as needed. Quite often in logic synthesis a bug may be fixed in the logic design and then the optimizations can be re-executed. This way the optimizations that were selected as the best optimizations can be re-applied or re-executed without re-launching the complete exploration again. The design explorer uses machine learning to select a set of optimizations that best fits a cost function for the nodes in a level of the tree.

### Implementation Example

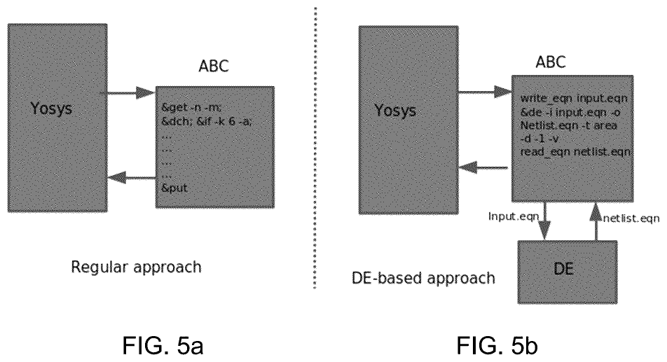

FIG. 5a is a block diagram illustrating an example of a prior approach to optimization where an RTL synthesis tool (e.g., Yosys) calls the logic synthesis tool (e.g., ABC). In contrast, an example user interface and implementation for the design explorer will now be described. FIG. 5b illustrates that the design explorer (DE) may process the combinational logic generated by an RTL synthesis tool (e.g., Yosys) which is passed on to a logic synthesis and verification tool for binary sequential logic circuits (e.g., ABC or LSOracle), and the design explorer may explore different optimizations and LUT mappings. The design explorer (DE) may be an extension of a synthesis and verification tool (e.g., ABC) capabilities. For instance, these combined tools may be called “ABC-DE”.

In the design explorer, a variety of different logic synthesis scripts for use with the logic synthesis tool (e.g., ABC or LSOracle) can be embedded within the design explorer but are not necessarily visible in a plugin that integrates the design explorer with the logic synthesis tool. The design explorer can take a logic synthesis tool's Boolean equations file(s) (an EQN file) as input and generate a new EQN file (the logic synthesis/mapping result). For instance, the EQN file can be improved by a third party without providing the flow from the RTL synthesis tool (e.g., Yosys).

The design explorer may be multi-threaded which means the design explorer can call or launch several threads to explore several logic implementations for a given target which may generally give a better quality of results (QoR). The design explorer may automatically call the functions of the synthesis tool (e.g., ABC or LSOracle) and is not sensitive if one synthesis tool call fails because multiple calls may be made to the synthesis tool. Therefore, the design explorer approach can be more robust as long as at least one call to the synthesis tool succeeds among all the calls made.

The design explorer may be executed from a synthesis suite (e.g., YoSys) through a synthesis tool (e.g., ABC or LOracle). The execution paths linking the synthesis suite, synthesis tool and the design explorer may be set up using environment variables in the synthesis suite or synthesis tool. Thus, the design explorer can be smoothly called through the synthesis tool (e.g., ABC). The design suite (e.g., Yosys) can activate the synthesis tool (e.g., ABC flow) which finally calls the design explorer (DE). The call from the synthesis tool (e.g., ABC) may be implemented as an example command which is ‘&de’.

At the synthesis suite level, the synthesis tool is called and modifications can be done in the synthesis tool script (or in the “synth_rs” built-in function) and the modifications are transparent for the flow. The synthesis tool may receive a set of Boolean logic and return a set of Boolean functions made of up to K inputs (if we map on K-input LUTs). When using the design explorer, for example, the synthesis tool can provide an input EQN file (e.g., “input.eqn”) that the design explorer can read, optimize/map and return through another EQN file (e.g., “netlist.eqn”).

As explained, the design explorer can be called from the synthesis tool through a new command that is usable from the synthesis named ‘&de’ (or another designated command name or reserved word can be used). This command may take the following example arguments i:
&de -i<input_eqn_file> -o<output_eqn_file> -t<target> -d<depth> -g -v
-i<input_eqn_file>: name of the EQN file describing the input Boolean equations to optimize and map.
-o<output_eqn_file>: name of the EQN file describing the optimized and mapped Boolean network (mapping up to K inputs, e.g. 6 here)
-t<target>: either “area” or “delay” or “mixed”, targeting either an area solution minimizing the number of LUTs, or a delay solution minimizing the max LUT path level or a mixed solution being a good trade off between area and delay (product of the number of LUTs and Max LUT Path level).
-d<depth>: an integer value between −1 and +infinity. It represents the max exploration depth, and a recommended value is around 10, 50, 100 depending on the size of the design. Generally, the value may be 100 for a small designs (−500 LUTs), 3 for a very big one (>20K LUTs), in general 11 to 21. There is an automatic mode with value −1 that can dynamically allow the exploration process to set the best value. Therefore, setting depth to −1 may be useful.
-g: if invoked then a tree graph can pop up to show the exploration process with all the be:
statistics, pruning, max limited, failures. This is only for analysis but not normal mode.
-v: if invoked then trace all information related to the thread's exploration. Generally, most used for analysis and not in normal mode.

In the synthesis script called by the synthesis tool, an example command may be:
&de -i input.eqn -o netlist.eqn -t area -d -1 -v

This command asks the synthesis tool (e.g., ABC or LOracle) to call the design explorer in order to read the EQN file “input.eqn” then explore a solution targeting area (number of LUTs), trace the exploration (-v), and then output the resulting mapped logic into file “netlist.eqn”. To have the synthesis tool script work correctly within the synthesis suite, the &de call can be encapsulated by providing the following:

| | |
|---|---|
| write_eqn input.eqn | // dump the EQN file that DE will read |
| &de -i input.eqn -o netlist.eqn ... | // call the de engine |
| read_eqn netlist.eqn | // read back the &de EQN result |

The design explorer interface may use a command line argument mechanism that is very close to the &de command used in the synthesis tool, and an example form is:
./de<input_eqn_file> <output_eqn_file> <target> <depth> <graph> <verbose>
where:
<input_eqn_file>: is the input .eqn file name
<output_end_file>: is the output .eqn file name
<target>: is an integer representing:
0: the target is area. Try to minimize the number of LUTs
1: the target is delay. Try to minimize Max Level of LUT logic with possibly minimum number of LUTs
2: the target is mixed. Try to get a good compromise between the number of LUTs and Max Level of LUT logic. It is for now: #LUTs * MaxLvl
<depth>: depth of the exploration tree. It can be between 0 (do nothing, just simple map) to any number close to 100. 100 will be for very small designs, such as less than 500 LUTs. For bigger designs it can be between 3 (>20K LUTs designs) and 20 (>2K LUTs designs).
−1 means that the depth can be defined dynamically along the exploration process. The −1 value is recommended for simple usage and a specific value is recommended for deep analysis.
<graph>: non 0 value tells the design explorer to pop up a graphical representation of the exploration tree. The best path leading to the best solution may be bolded. The tree may show the pruned and maxThreadLimited calls.
<verbose>: non 0 value tells the design explorer to show the exploration statistics along the process.

The design explorer can launch many threads and each thread can call the synthesis tool (e.g., ABC) and can apply a specific synthesis tool script on a specific logic network. The basic process may have at least three steps:
1. Characterize the logic: try to get the estimated number of LUTs to use the appropriate optimization/mapping functions to avoid runtime blow up.
2. Perform a first pass of “initialFlow” where the idea is to try 1 or 2 or 3 optimizations and mapping strategies in parallel to start with a good solution. Then the best one is selected at the end using a “selectBestInit” operation.
3. Loop on two categories of optimization/mapping commands
   a. commands stored in container “mapCommands”
   b. then commands stored in container “postMapCommands”
   c. Exit when some conditions are met

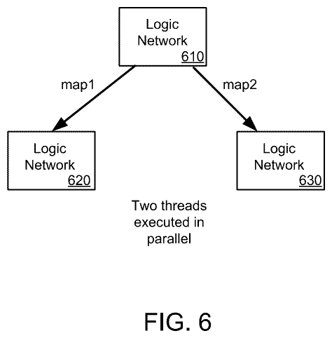

FIG. 6 illustrates that at each exploration layer, the current logic network 610 can be used as a starting point and then selected commands stored in a container (as defined by the user or designer) can be applied to the current logic network. For example, if container “mapCommands” has two commands “map1” and “map2” then the design explorer can apply these two commands in parallel on the logic network 610 selected by “selectBestInit”. Applying these commands may result in two new transformed logic networks 620, 630. FIG. 6 illustrates that once the two commands/threads complete, then processing may move to the next exploration layer. This is a breadth first approach exploration path, and the threads may complete at the same depth before moving on to the next depth.

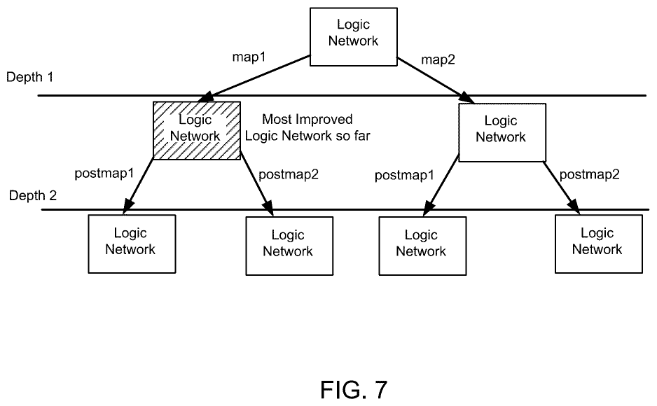

Once the threads of the “mapCommands” container is complete then for the second “explore” layer the commands stored in the container “postmapCommands” can be applied on each leaf of the exploration tree. If for instance, “postmap1” and “postmap2” commands exist, the tree may look something like FIG. 7, which illustrates that the exploration tree may grow by looping each time on the set of “mapCommands” then “postmapCommands”.

As discussed, the exploration tree may tend to explode, and therefore, strategies may be used to avoid such tree explosions. At least two mechanisms can be used to reduce the explosion. The first method is pruning. At each depth level logic network which are too far (i.e., by a defined measure) from the current logic network can be rejected. For example, for area optimization a logic network which has 10% more LUTs than the current logic network may be rejected.

The second method is limiting the maximum number of threads. There may be a max limit of threads to use which may be MAX_THREADS (for example: 25) therefore at any depth “d” only MAX_THREADS threads can be executed. In order to have the best return on investment, the logic networks at depth ‘d−1’ may be sorted according to the target cost function (ex: in Area optimization logic networks may be sorted from min number of LUTs to max number of LUTs) and the process will explore at depth ‘d’ only the MAX_THREADS first logic networks in this sorted list, and the other logic networks may be ignored. These two mechanisms can help to control the size of the exploration tree without degrading the QoR too much.

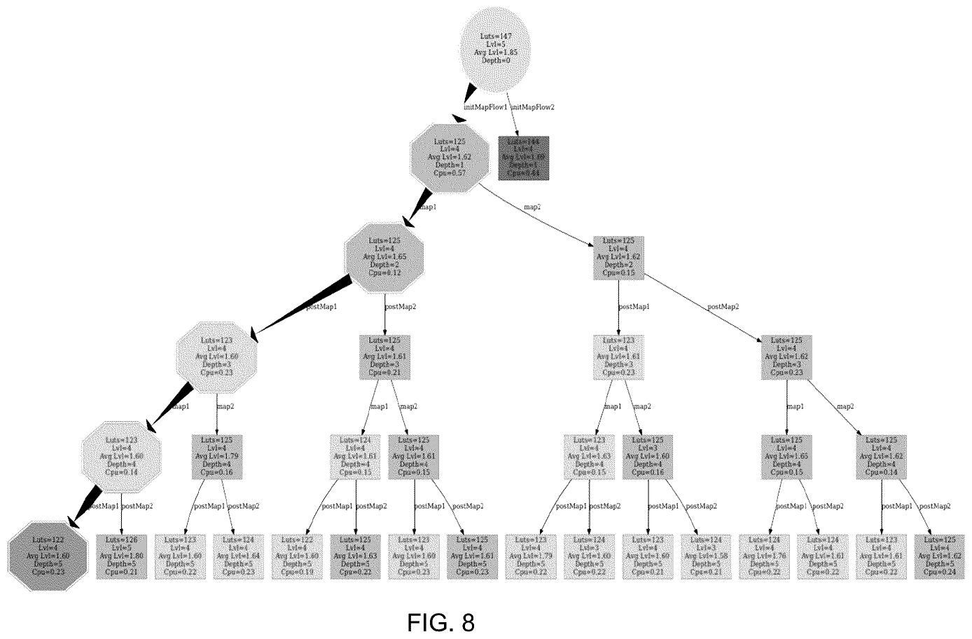

FIG. 8 illustrates an exploration tree obtained with the <graph> option set to 1 with a depth 5. In FIG. 8, the hexagonal nodes show the path that leads to the min number of LUTs solution with 122 LUTs.

From the start node, two initMapFlow runs are applied, then only “initMapFlow1” is selected and then the breadth first exploration can try the optimizations of “map1”, “map2, “postmap1” and “postmap2” with all combinations.

The definitions of “map1”, “map2”, . . . representing specific optimizations and mappings of the logic network are straightforward to express in the design explorer. The definitions of the optimizations may be simply expressed as a string (ex: “string map1=“&st; &if -K 6 -a;”) and may be added in an optimization container by doing:
mapCommands→push_back(map1);
   as a map command or:
postmapCommands→push_back(map1);
   as a postmap command.

Since the exploration tree can explode at some given depth, the “pruning” and “max Thread Limited” restrictions can be applied. If level 6 in the tree is reached, some “max thread limited” cuts may be made so that there are at most 25 leaves/threads. The cuts may have been performed on the least interesting logic networks. These cuts can also occur with pruning (e.g. rejecting a poor solution even the MAX_THREADS limit was not reached yet). The pruned cases may correspond to logic networks that look comparatively poor and are deemed to not be worth further exploration.

In alternative configurations of design explorer, more exploration/threads may be used at the beginning of exploring a tree, while constrained exploration and/or threads may be used as the tree grows. For example, one or two initMapFlow may be applied and the tree starts to grow to 2 thread, then 4 threads, . . . N threads. The tree may be not as large at the beginning so there is some room to run more threads at the beginning until the MAX_THREADS limit (e.g., 25) is reached. Setting the maximum thread limit to 15, 10 or less may be possible without degrading the QoR. The goal may be to reduce machine overloading with seeing a degradation in quality of results (QoR).

The use of the design explorer may be improved with respect to more complex usage or scenarios where it may be called by the synthesis suite several times. When the design explorer is called, different levels of optimization may be applied. More specifically:
1. 1st time: a shorter design explorer session may help do initial simplifications.
2. 2nd time: a full blown exploration with full optimization and mapping.

A “quick” design explorer optimization may be applied for the first call and especially a quick, light “InitMapFlow” script for big designs. In a similar example, the system can use a new different mapping: the “&st; &if -sz -C 6 -K 11 -S 66 -a” followed by classical “mfs2” and “&satlut” as an optimization. It is slow though, so the “-C” option (e.g., -C4) option may be used to reduce runtime overhead but that may be traded for QoR.

In another configuration, to address runtime concerns, the scripts at a given depth (all the map* or the postmap*) can preferably take about the same amount of time to process. This can avoid situations where one script or thread is very fast but has to wait frequently for the second script/thread to complete. In design explorer, the total runtime is the sum of the worst runtime at each depth. Therefore, to reduce runtime at least two variables may be used:
1. Depth: reducing a depth value can reduce run time.
2. Script complexity: reducing the time complexity of the most complex script for a given depth/stage: InitMapFlow, map, postMap can reduce run time.

Another configuration of the design explorer for a mixed optimization target may be to investigate an AREA target in a first design explorer call from a synthesis tool or synthesis suite and then investigate MIXED/DELAY for second call of a synthesis suite.

The design explorer may use a cache mechanism where the “input.eqn” given to the design explorer can be stored and if the “input.eqn” is later the same as the one processed sometime earlier, the system can return right away the corresponding “netlist.eqn” if the same target is being addressed. An encrypted storage and caching mechanism can be provided that stores pairs (input.eqn, netlist.eqn) for look-up to see if the design explorer is called with the same exact input parameters, e.g. same “input.eqn” and same optimization target (area, delay, mixed).

### EXPERIMENTAL RESULTS

In this section, some experimental results were obtained from using the exploration engine (e.g., ABC-DE) when challenging the best results in the EPFL benchmark suite. EPFL is an international competition, that keeps track of the best LUT6 count and level count synthesized designs. It is made of 10 purely arithmetic and 10 classical random benchmarks. 20 benchmarks are provided and since those can be synthesized in minimum LUT6 count mode or in minimum level count mode, there are 40 benchmarks to consider. EPFL is also made of three multi-million netlist designs and therefore there are 6 extra benchmarks for those two optimization modes. Among these 46 benchmarks, the present optimization engine (e.g., ABC-DE) is able to get 31 new unique winners and 6 ties versus current previously existing best results. This means that the exploration engine is able to deliver 37 best results over a total of 46 benchmarks. Some of benchmarks have been improved significantly by the exploration engine such as “arbiter’ in level count (370 LUTs instead of 1036), “router” in LUT count mode with 19 LUTs instead of 50, and several deeply studied designs in the past with 5 to 20% LUT count reduction.

An optimal solution is also provided by the present technology regarding the “adder” benchmark with 129 LUT6. This “adder” benchmark has been studied for quite some time and the scientific community could not find a better solution than 192 LUT6 to map this design. Despite many studies, this design improved by only 1 LUT since 2016 and then in July 2022 to 134 LUTs. The design explorer (e.g., ABC-DE) output 129 LUTs and this is the optimal solution since this design has 129 outputs and none of them can be shared.

The design explorer (e.g., ABC-DE) has been integrated in an open-source based flow using “Yosys” as the main RTL synthesis flow. It has been shown that versus a previous ABC script expert solution, the design explorer (e.g., ABC-DE) may deliver a 20% LUT count reduction as applied to an internal golden suite of 185 industrial designs. This shows the significant QoR benefit of the present technology.

The design explorer engine (e.g., ABC-DE) can perform dynamic exploration of ABC synthesis scripts for LUT mapping to improve QoR. The design explorer engine can use a breadth-first implementation and can provide solutions to deal with run-time explosion and being stuck at local minimum situations. The design explorer engine is able to get 37 best results out of 46 in term of LUT count and level count minimization, improving many benchmarks that were thought to be not improvable. The design explorer engine helps also to get around 20% LUT count reduction versus an expert ABC script solution. This technology has been integrated in an industrial tool performing around 12% LUT count reduction on a typical set of designs versus previously known systems.

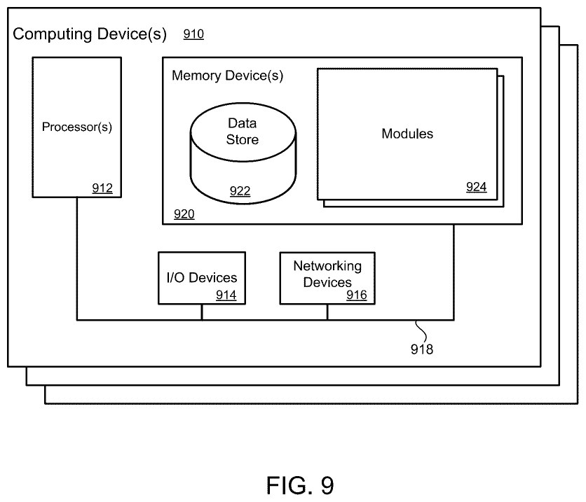

FIG. 9 illustrates a computing device 910 which can execute the foregoing subsystems of this technology. The computing device 910 and the components of the computing device 910 described herein can correspond to the servers, client devices and/or the computing devices described above. The computing device 910 is illustrated on which a high level example of the technology can be executed. The computing device 910 can include one or more processors 912 that are in communication with memory devices 920. The computing device can include a local communication interface 918 for the components in the computing device. For example, the local communication interface can be a local data bus and/or any related address or control busses as can be desired.

The memory device 920 can contain modules 924 that are executable by the processor(s) 912 and data for the modules 924. The modules 924 can execute the functions described earlier. A data store 922 can also be located in the memory device 920 for storing data related to the modules 924 and other applications along with an operating system that is executable by the processor(s) 912.

Other applications can also be stored in the memory device 920 and can be executable by the processor(s) 912. Components or modules discussed in this description that can be implemented in the form of software using high programming level languages that are compiled, interpreted or executed using a hybrid of the methods.

The computing device can also have access to I/O (input/output) devices 914 that are usable by the computing devices. An example of an I/O device is a display screen that is available to display output from the computing devices. Other known I/O device can be used with the computing device as desired. Networking devices 916 and similar communication devices can be included in the computing device. The networking devices 916 can be wired or wireless networking devices that connect to the Internet, a LAN, WAN, or other computing network.

The components or modules that are shown as being stored in the memory device 920 can be executed by the processor 912. The term “executable” can mean a program file that is in a form that can be executed by a processor 912. For example, a program in a higher level language can be compiled into machine code in a format that can be loaded into a random access portion of the memory device 920 and executed by the processor 912, or source code can be loaded by another executable program and interpreted to generate instructions in a random access portion of the memory to be executed by a processor. The executable program can be stored in any portion or component of the memory device 920. For example, the memory device 920 can be random access memory (RAM), read only memory (ROM), flash memory, a solid state drive, memory card, a hard drive, optical disk, floppy disk, magnetic tape, or any other memory components.

The processor 912 can represent multiple processors and the memory 920 can represent multiple memory units that operate in parallel to the processing circuits. This can provide parallel processing channels for the processes and data in the system. The local interface 918 can be used as a network to facilitate communication between any of the multiple processors and multiple memories. The local interface 918 can use additional systems designed for coordinating communication such as load balancing, bulk data transfer, and similar systems.

While the flowcharts presented for this technology can imply a specific order of execution, the order of execution can differ from what is illustrated. For example, the order of two more blocks can be rearranged relative to the order shown. Further, two or more blocks shown in succession can be executed in parallel or with partial parallelization. In some configurations, one or more blocks shown in the flow chart can be omitted or skipped. Any number of counters, state variables, warning semaphores, or messages might be added to the logical flow for purposes of enhanced utility, accounting, performance, measurement, troubleshooting or for similar reasons.

Some of the functional units described in this specification may represent modules, in order to more particularly emphasize their implementation independence. For example, a module can be implemented as a hardware circuit comprising custom Very Large Scale Integration (VLSI) circuits or gate arrays, off-the-shelf semiconductors such as logic chips, transistors, or other discrete components. A module can also be implemented in programmable hardware devices such as field programmable gate arrays, programmable array logic, programmable logic devices or the like.

Modules can also be implemented in software for execution by various types of processors. An identified module of executable code can, for instance, comprise one or more blocks of computer instructions, which can be organized as an object, procedure, or function. Nevertheless, the executables of an identified module need not be physically located together, but can comprise disparate instructions stored in different locations which comprise the module and achieve the stated purpose for the module when joined logically together.

Indeed, a module of executable code can be a single instruction, or many instructions, and can even be distributed over several different code segments, among different programs, and across several memory devices. Similarly, operational data can be identified and illustrated herein within modules, and can be embodied in any suitable form and organized within any suitable type of data structure. The operational data can be collected as a single data set, or can be distributed over different locations including over different storage devices. The modules can be passive or active, including agents operable to perform desired functions.

The devices described herein can also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example, and not limitation, communication media includes wired media such as a wired network or direct-wired connections, and wireless media such as acoustic, radio frequency, infrared, and other wireless media. The term computer readable media as used herein includes communication media.

Reference was made to the examples illustrated in the drawings, and specific language was used herein to describe the same. It will nevertheless be understood that no limitation of the scope of the technology is thereby intended. Alterations and further modifications of the features illustrated herein, and additional applications of the examples as illustrated herein, which would occur to one skilled in the relevant art and having possession of this disclosure, are to be considered within the scope of the description.

In describing the present technology, the following terminology will be used: The singular forms “a,” “an,” and “the” include plural referents unless the context clearly dictates otherwise. Thus, for example, reference to an item includes reference to one or more items. The term “ones” refers to one, two, or more, and generally applies to the selection of some or all of a quantity. The term “plurality” refers to two or more of an item. The term “about” means quantities, dimensions, sizes, formulations, parameters, shapes and other characteristics need not be exact, but can be approximated and/or larger or smaller, as desired, reflecting acceptable tolerances, conversion factors, rounding off, measurement error and the like and other factors known to those of skill in the art. The term “substantially” means that the recited characteristic, parameter, or value need not be achieved exactly, but that deviations or variations including, for example, tolerances, measurement error, measurement accuracy limitations and other factors known to those of skill in the art, can occur in amounts that do not preclude the effect the characteristic was intended to provide. Numerical data can be expressed or presented herein in a range format. It is to be understood that such a range format is used merely for convenience and brevity and thus should be interpreted flexibly to include not only the numerical values explicitly recited as the limits of the range, but also interpreted to include all of the individual numerical values or sub-ranges encompassed within that range as if each numerical value and sub-range is explicitly recited.

As an illustration, a numerical range of “about 1 to 5” should be interpreted to include not only the explicitly recited values of about 1 to about 5, but also include individual values and sub-ranges within the indicated range. Thus, included in this numerical range are individual values such as 2, 3 and 4 and sub-ranges such as 1-3, 2-4 and 3-5, etc. This same principle applies to ranges reciting only one numerical value (e.g., “greater than about 1”) and should apply regardless of the breadth of the range or the characteristics being described. A plurality of items can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Furthermore, where the terms “and” and “or” are used in conjunction with a list of items, they are to be interpreted broadly, in that any one or more of the listed items can be used alone or in combination with other listed items. The term “alternatively” refers to selection of one of two or more alternatives, and is not intended to limit the selection to only those listed alternatives or to only one of the listed alternatives at a time, unless the context clearly indicates otherwise. The term “coupled” as used herein does not require that the components be directly connected to each other. Instead, the term is intended to also include configurations with indirect connections where one or more other components can be included between coupled components. For example, such other components can include amplifiers, attenuators, isolators, directional couplers, redundancy switches, and the like. Also, as used herein, including in the claims, “or” as used in a list of items prefaced by “at least one of” indicates a disjunctive list such that, for example, a list of “at least one of A, B, or C” means A or B or C or AB or AC or BC or ABC (i.e., A and B and C). As used herein, a “set” of elements is intended to mean “one or more” of those elements, except where the set is explicitly required to have more than one or explicitly permitted to be a null set.

Modules may also be implemented in software for execution by various types of processors. An identified module of executable code may, for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices. The modules may be passive or active, including agents operable to perform desired functions.

The technology described here can also be stored on a computer readable storage medium that includes volatile and non-volatile, removable and non-removable media implemented with any technology for the storage of information such as computer readable instructions, data structures, program modules, or other data. Computer readable storage media include, but is not limited to, RAM, ROM, EEPROM, flash memory or other memory technology, CD-ROM, digital versatile disks (DVD) or other optical storage, magnetic cassettes, magnetic tapes, magnetic disk storage or other magnetic storage devices, or any other computer storage medium which can be used to store the desired information and described technology.

The devices described herein may also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example, and not limitation, communication media includes wired media such as a wired network or direct-wired connection, and wireless media such as acoustic, radio frequency, infrared, and other wireless media. The term computer readable media as used herein includes communication media.

Furthermore, the described features, structures, or characteristics may be combined in any suitable manner in one or more examples. In the preceding description, numerous specific details were provided, such as examples of various configurations to provide a thorough understanding of examples of the described technology. One skilled in the relevant art will recognize, however, that the technology can be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements can be devised without departing from the spirit and scope of the described technology.

1. A method for improvement of a Boolean Network, comprising:
applying a first plurality of transformation scripts to a Boolean Network, wherein the first plurality of transformation scripts result in transformation metrics that are represented as nodes in a level of a transformation tree;
prioritizing the nodes in the level of the transformation tree based in part on a cost function that uses the transformation metrics to identify an improved node as compared to less improved nodes;
removing nodes in the level of the transformation tree from consideration that are less improved as defined by the cost function and compared to improved nodes;
repeating the applying, sorting, and removing steps for a second plurality of transformation scripts for the Boolean Network to form a second level of the transformation tree; and
identifying a transformation path using nodes of the transformation tree that include the improved nodes.

2. The method as in claim 1, wherein identifying a transformation path further comprises identifying a transformation path through nodes of the transformation tree that has a desirable cost as defined by the cost function and has a reduced logic solution compared to other paths in the transformation tree.

3. The method as in claim 1, wherein prioritizing nodes further comprises:
selecting the improved node that minimizes the cost function; and
placing the improved node in a transformation path.

4. The method as in claim 1, further comprising:
applying a plurality of fine grained transformations to the Boolean Network to create a first set of nodes in the transformation tree; and
applying a plurality of coarse grained transformations to the Boolean Network to create a second set of nodes in the transformation tree that descend from the first set of nodes created by the plurality of fine grained transformations.

5. The method as in claim 4, further comprising repeating the fine grained transformations and coarse grained transformations until a defined number of iterations is reached or until improvements in transformation metrics stop occurring.

6. The method as in claim 1, further comprising executing the transformation scripts using an individual process to execute each transformation script.

7. The method as in claim 6, further comprising executing transformation scripts for the Boolean Network using multi-threading with an upper bound value for a number of individual processes to be used per level of the transformation tree.

8. The method as in claim 1, wherein an optimization goal of the transformation path is at least one of: a reduced chip wafer area, a reduced delay, a power minimization or an improved combination of reduced chip wafer area, reduced delay and power minimization.

9. The method as in claim 1, wherein the transformation scripts are applied incrementally and the first plurality of transformation scripts have smaller modifications than the second plurality of transformation scripts.

10. The method as in claim 1, wherein fine grained transformations are applied for the first plurality of transformation scripts and the fine grained transformations provide a smallest available unit of logic reduction.

11. The method as in claim 1, further comprising recording a transformation path from the transformation tree with improved nodes and a reduced logic solution for later application to the Boolean Network.

12. The method as in claim 1, further comprising tracking statistics for transformation scripts wherein improved nodes are selected to determine which transformation scripts to include in the transformation path.

13. The method as in claim 1, further comprising tracking statistics for transformation scripts which are not selected to determine which transformation scripts to discard due to lack of use or lack of improved output.

14. A system for improvement of a Boolean Network, comprising:
at least one processor;
at least one memory device including a data store to store a plurality of data and instructions that, when executed, cause the system and processor to:
apply a first plurality of transformation scripts to a Boolean Network, wherein first plurality of transformation scripts generate transformation metrics which are stored in nodes in a level of a transformation tree;
prioritize the nodes in levels of tree based in part on a cost function that uses the transformation metrics in order to identify an improved node using the cost function as compared to other less improved nodes;
prune nodes in the level of the transformation tree that are less improved as defined by the cost function and compared to the improved node;
repeating the apply, sort, and prune steps for a second plurality of transformation scripts for the Boolean Network to form a second level of the transformation tree; and
identifying a transformation path using nodes of the transformation tree that include the improved nodes from individual levels of the transformation tree.

15. The system as in claim 14, further comprising:
applying a plurality of fine grained transformations to the Boolean Network to create a first set of nodes in the transformation tree; and
applying a plurality of coarse grained transformations to the Boolean Network to create a second set of nodes in the transformation tree that descend from the first set of nodes created by the fine grained transformations.

16. A method for improvement of a Boolean Network, comprising:
applying a plurality of transformation scripts to a Boolean Network to form a plurality of levels of a transformation tree with nodes representing transformation metrics for the transformation scripts applied to the Boolean Network;
prioritizing the nodes in individual levels of the transformation tree based in part on a cost function that uses the transformation metrics to identify an improved node as compared to less improved nodes;
pruning nodes in levels of the transformation tree that are less improved as defined by the cost function and as compared to other nodes in the level of the transformation tree; and
identifying a transformation path using improved nodes of the transformation tree.

17. The method as in claim 16, wherein sorting the nodes in levels of the transformation tree to prioritize nodes further comprises:
selecting the improved node that minimizes the cost function; and
recording the improved node in the transformation path.

18. The method as in claim 16, further comprising:
applying a plurality of fine grained transformation modifications to the Boolean Network to create a first set of nodes in the transformation tree; and
applying a plurality of coarse grained transformations to the Boolean Network to create a second set of nodes in the transformation tree that descend from the first set of nodes created by the plurality of fine grained transformations.

19. The method as in claim 16, further comprising executing the transformation scripts on the Boolean Network using multi-threading with an upper bound value for a number of individual processes to be used per level of the transformation tree.

20. A method for improvement of a Boolean Network, comprising:
applying a plurality of transformation scripts to a Boolean Network to form a plurality of levels of a transformation tree with nodes representing transformation metrics for the transformation scripts applied to the Boolean Network;
prioritizing the nodes in individual levels of the transformation tree based in part on a cost function that uses the transformation metrics to identify an improved node as compared to less improved nodes in each of the plurality of levels; and
identifying a transformation script using improved nodes of the transformation tree.
